(19) United States
(12) Patent Application Publication
(10) Pub. No.: US 2026/0058664 A1
(43) Pub. Date: Feb. 26, 2026

(54) CLOCK GENERATOR AND DEVICE INCLUDING THE SAME

(71) Applicant: Samsung Electronics Co., Ltd., Suwon-si (KR)

(72) Inventors: Wooseok CHOI, Seoul-si (KR); Jia PARK, Seoul-si (KR)

(73) Assignees: Samsung Electronics Co., Ltd., Suwon-si (KR); SEOUL NATIONAL UNIVERSITY R&DB FOUNDATION, Seoul (KR)

(21) Appl. No.: 19/275,177

(22) Filed: Jul. 21, 2025

(30) Foreign Application Priority Data
Aug. 20, 2024 (KR) 10-2024-0111635
Nov. 5, 2024 (KR) 10-2024-0155688

(51) Int. Cl. H03L 7/085; G04F 10/00; H03L 7/08; H03L 7/099; H03M 1/66; H03M 1/82

(52) U.S. Cl. CPC H03L 7/085; G04F 10/00; H03L 7/0807; H03L 7/099; H03M 1/662; H03M 1/82

(57) ABSTRACT

Provided is a clock generator including a Digital-to-Time Converter (DTC) configured to output a second reference clock signal by adjusting a phase of a first reference clock signal, an oscillator configured to generate a local clock signal synchronized with an edge of the second reference clock signal, a phase detector configured to generate a phase error value, and a DTC control circuit configured to output a DTC code, wherein, in response to the DTC code matching a bound reference code, the DTC control circuit is configured to update the DTC code to a rollover target code.

### CROSS-REFERENCE TO RELATED APPLICATION

This application is based on and claims priority under 35 U.S.C. § 119 to Korean Patent Application No. 10-2024-0111635, filed on Aug. 20, 2024, and No. 10-2024-0155688, filed on Nov. 5, 2024, in the Korean Intellectual Property Office, the disclosures of which are incorporated by reference herein in their entireties.

### BACKGROUND

The inventive concept relates to a clock generator, and more particularly, to a clock generator capable of generating multi-phase clock signals with high frequencies based on low-frequency single-phase reference clocks, and a device including the clock generator.

A high-speed link architecture, such as Peripheral Component Interconnect Express (PCIe), may adopt a configuration in which a plurality of parallel local lanes share a single global clock generator to increase the bandwidth. Each local lane may perform data recovery by adjusting the phase of clocks distributed by the global clock generator, such as a Phase Locked Loop (PLL). The high-speed link architecture may use sub-rate clocks and data recovery to accommodate the increased bandwidth, in which case a multi-phase clock may be required.

The high-speed link architecture may have two major issues. First, distributing clocks using a high-frequency reference clock may significantly increase the amount of power consumed by a device. Second, the number of phase interpolators required may increase in proportion to the necessary clock phases. In this case, the phase interpolators may have complex designs due to characteristics thereof; thus, the phase interpolators may consume an enormous amount of power, and the area occupied by the phase interpolators in the device may increase. In other words, both power efficiency and area efficiency of the device may degrade.

Accordingly, there is a need for methods of improving the performance and efficiency of high-speed data transmission devices without degrading their power and area efficiency.

### SUMMARY

The inventive concept aims to reduce the power consumption of a device by replacing phase interpolators with a local clock generator and to decrease the circuit area required to implement the device.

Technical problems of the inventive concept are not limited to those mentioned above, and other technical problems may be clearly understood by one of ordinary skill in the art from the descriptions below.

According to an example embodiment, there is provided a clock generator including a Digital-to-Time Converter (DTC) configured to receive a first reference clock signal from outside the clock generator, and output a second reference clock signal by adjusting a phase of the first reference clock signal received from outside the clock generator based on DTC code, an oscillator configured to generate a local clock signal synchronized to have a rising edge at an edge of the second reference clock signal, a phase detector configured to generate a phase error value based on a phase difference between the local clock signal and the second reference clock signal, and a DTC control circuit configured to output the DTC code based on the phase error value and phase information received from outside the clock generator, and update the DTC code to a rollover target code in response to the DTC code matching a bound reference code, and the oscillator being configured to adjust a phase such that the local clock signal has a falling edge at an edge of the second reference clock signal corresponding to the rollover target code.

According to another example embodiment, there is provided a clock generator including a DTC configured to receive a first reference clock signal from outside the clock generator, and output a second reference clock signal by adjusting the phase of the first reference clock signal based on a DTC code, a pulse generator configured to generate an injection signal corresponding to an edge of the second reference clock signal during each period of the second reference clock signal, an oscillator configured to generate a local clock signal with a phase synchronized with the injection signal, in response to the injection signal, a phase detector configured to generate a phase error value based on a phase difference between the local clock signal and the second reference clock signal, a rollover logic circuit configured to output an estimation code based on the phase error value, an accumulator configured to output a phase code based on a value obtained by accumulating values represented by phase information received from outside the clock generator, a multiplexer configured to output, as the DTC code, the phase code or the estimation code, and the rollover logic circuit being further configured to provide the estimation code to the accumulator as a rollover code, in response to the DTC code matching a bound reference code.

According to another example embodiment, there is provided a device including a Phase Locked Loop (PLL) configured to generate a first reference clock signal, a clock generator configured to generate a local clock signal based on the first reference clock signal, and a Clock and Data Recovery (CDR) circuit configured to output phase information of the local clock signal based on the local clock signal and data received from the outside, wherein the clock generator includes a DTC configured to output a second reference clock signal by adjusting a phase of the first reference clock signal received from the PLL, based on DTC code, an oscillator configured to generate a local clock signal synchronized to have a rising edge at an edge of the second reference clock signal, a phase detector configured to generate a phase error value based on a phase difference between the local clock signal and the second reference clock signal, and a DTC control circuit configured to output the DTC code based on the phase error value and phase information received from the CDR circuit, wherein, in response to the DTC code matching a bound reference code, the DTC control circuit is configured to update the DTC code to a rollover target code, and the oscillator is configured to adjust a phase such that the local clock signal has a falling edge at an edge of the second reference clock signal corresponding to the rollover target code.

In further example embodiments, a method for use in a clock generator comprises: receiving a first reference clock signal from outside the clock generator, generating a second reference clock signal by adjusting a phase of the first reference clock signal based on a DTC code; generating a local clock signal synchronized to have a rising edge at an edge of the second reference clock signal; generating a phase error value based on a phase difference between the local clock signal and the second reference clock signal; and generating a DTC code based on the phase error value and phase information received from outside the clock generator; updating the DTC code to a rollover target code in response to the DTC code matching a bound reference code; and adjusting a phase of the second reference clock signal such that the local clock signal has a falling edge at the edge of the second reference clock signal corresponding to the rollover target code.

In some such example embodiments, a frequency of the first reference clock signal is lower than a frequency of the local clock signal. In other example embodiments, a method also includes generating an injection signal corresponding to the edge of the second reference clock signal during each period of the second reference clock signal, such that a phase of the local clock signal is synchronized with the injection signal in response to the injection signal.

In yet further example embodiments, a method comprises generating a phase code by accumulating values represented by the phase information; selecting the phase code or an estimation code as the DTC code; and selecting the estimation code and generating the estimation code based on the phase error value.

In some example embodiments, the phase information corresponds to any one of a first phase value, which indicates that the phase of the local clock signal is advanced, or a second phase value, which indicates that the phase of the local clock signal is delayed.

In yet other example embodiments a method includes, in response to the DTC code matching the bound reference code, providing a rollover code corresponding to the estimation code to an accumulator, generating the rollover target code by accumulating the rollover code to the phase code, and outputting the rollover target code as the DTC code.

### BRIEF DESCRIPTION OF THE DRAWINGS

Example embodiments will be more clearly understood from the following detailed description taken in conjunction with the accompanying drawings in which:

FIG. 1 is a block diagram of a system according to an example embodiment;

FIG. 2 is a block diagram of a first device according to an example embodiment;

FIG. 3 is a block diagram of a receiver according to an example embodiment;

FIG. 4 is a timing diagram showing signals according to an example embodiment;

FIGS. 5A to 7B illustrate changes in a Digital-to-Time Converter (DTC) code and corresponding timing diagrams according to an operation of a receiver, according to an example embodiment;

FIG. 8 illustrates changes in a DTC code according to an operation of a receiver, according to an example embodiment;

FIGS. 9A to 9D are graphs for describing an operation of a clock generator, according to an example embodiment;

FIGS. 10A to 12B are graphs for describing an operation of a clock generator, according to an example embodiment;

FIGS. 13A and 13B are graphs for describing estimation modes according to an example embodiment; and

FIG. 14 is a block diagram of a system including a device, according to example embodiments.

### DETAILED DESCRIPTION OF THE EXAMPLE EMBODIMENTS

Hereinafter, one or more example embodiments are described in detail with reference to the attached drawings. When describing with reference to drawings, like or corresponding components are assigned the same reference numerals, and repeated descriptions thereof are omitted.

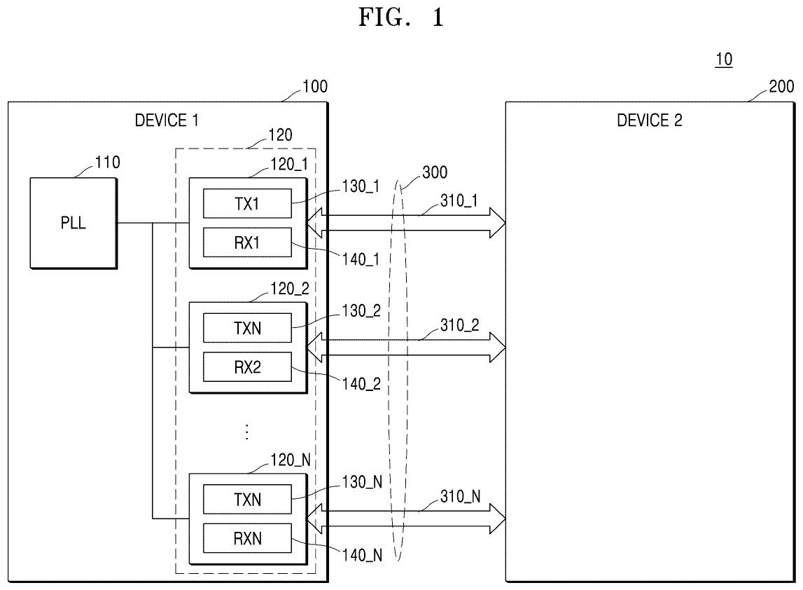

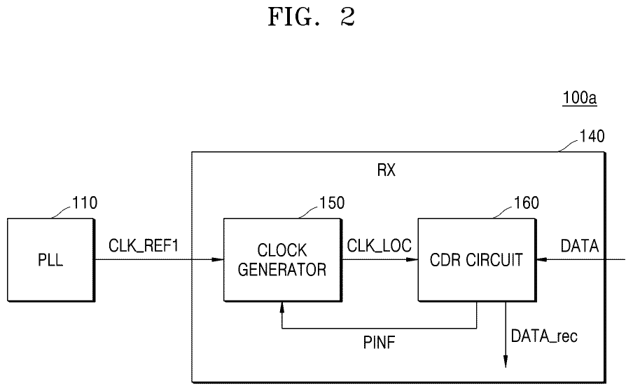

FIG. 1 is a block diagram of a system 10 according to an example embodiment.

Referring to FIG. 1, the system 10 may include a first device 100 and a second device 200. The first device 100 and the second device 200 may exchange data through an interface 300.

The interface 300 may enable data exchange between the first device 100 and the second device 200 through a first lane 310_1 to an N^{th} lane 310_N (where, N is a natural number of at least two). In an example embodiment, the interface 300 may comply with Peripheral Component Interconnect Express (PCIe) standards; however, this is only an example and is not intended to limit the inventive concept recited by the appended claims.

The first device 100 may include a Phase Locked Loop (PLL) 110 and an interconnect circuit 120. The PLL 110 may generate a reference clock signal and provide the same to the interconnect circuit 120. In an example embodiment, the reference clock signal may be a low-frequency clock signal.

The interconnect circuit 120 may include physical components for exchanging data. The interconnect circuit 120 may include a first transceiver circuit 120_1 to an N^{th} transceiver circuit 120_N. The first transceiver circuit 120_1 to the N^{th} transceiver circuit 120_N may each include a transmitter TX and a receiver RX. For example, the first transceiver circuit 120_1 may include a first transmitter 130_1 and a first receiver 140_1. The second transceiver circuit 120_2 may include a second transmitter 130_2 and a second receiver 140_2. The N^{th} transceiver circuit 120_N may include an N^{th} transmitter 130_N and an N^{th} receiver 140_N.

In an example embodiment, the first transceiver circuit 120_1 may exchange data with the second device 200 through the first lane 310_1. The second transceiver circuit 120_2 may exchange data with the second device 200 through the second lane 310_2. The N^{th} transceiver circuit 120_N may exchange data with the second device 200 through the N^{th} lane 310_N.

FIG. 2 is a block diagram of a first device 100a according to an example embodiment. FIG. 2 may be described with reference to FIG. 1, and repeated descriptions thereof may be omitted.

Referring to FIG. 2, the first device 100a may correspond to the first device 100 of FIG. 1. The first device 100a may include a PLL 110 and a receiver 140. The receiver 140 may correspond to any one of the first receiver 140_1 to the N^{th} receiver 140_N of FIG. 1.

The PLL 110 may generate a first reference clock signal CLK_REF1. The PLL 110 may provide the generated first reference clock signal CLK_REF1 to the clock generator 150 of the receiver 140.

In an example embodiment, the first reference clock signal CLK_REF1 may be a low-frequency clock signal. For example, the frequency of the first reference clock signal LK_REF1 may be lower than that of a local clock signal CLK_LOC.

The receiver 140 may include the clock generator 150 and a Clock and Data Recovery (CDR) circuit 160. The receiver 140 may generate the local clock signal CLK_LOC and recovered data DATA_rec based on the first reference clock signal CLK_REF1 from the PLL 110 and data DATA from the second device (200 of FIG. 1).

The clock generator 150 may generate the local clock signal CLK_LOC based on the first reference clock signal CLK_REF1. The clock generator 150 may receive phase information PINF from the CDR circuit 160. The clock generator 150 may adjust the phase of the local clock signal CLK_LOC that is output from the clock generator 150, based on a value represented by the phase information PINF.

In an example embodiment, the local clock signal CLK_LOC may be a multi-phase clock signal. For example, the local clock signal CLK_LOC may be a 4-phase clock signal.

In an example embodiment, the local clock signal CLK_LOC may be a high-frequency clock signal. For example, the frequency of the local clock signal CLK_LOC may be higher than that of the first reference clock signal CLK_REF1.

The CDR circuit 160 may be configured to extract a clock signal from the data DATA and sample the data DATA by using the extracted clock signal, thus outputting the recovered data DATA_rec.

The CDR circuit 160 may compare the clock signal, which is extracted from the data DATA, with the local clock signal CLK_LOC, generate phase information PINF regarding the local clock signal CLK_LOC, and provide the phase information PINF to the clock generator 150.

In an example embodiment, when the phase of the local clock signal CLK_LOC is ahead of the clock signal extracted from the data DATA by the CDR circuit 160, the CDR circuit 160 may output phase information PINF with a first phase value (e.g., “1”) indicating that the phase of the local clock signal CLK_LOC is advanced.

In an example embodiment, when the phase of the local clock signal CLK_LOC lags behind the clock signal extracted from the data DATA by the CDR circuit 160, the CDR circuit 160 may output phase information PINF with a second phase value (e.g., “−1”) indicating that the phase of the local clock signal CLK_LOC is delayed.

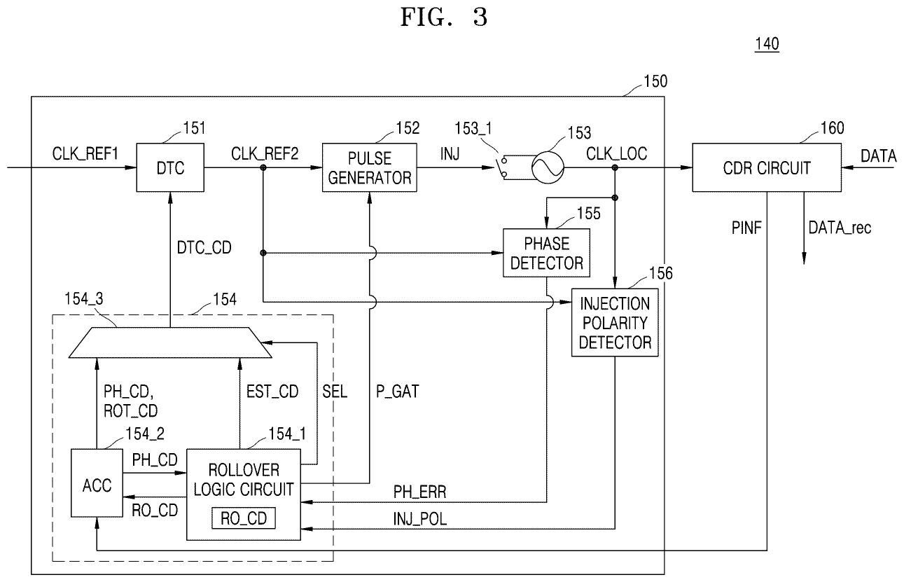

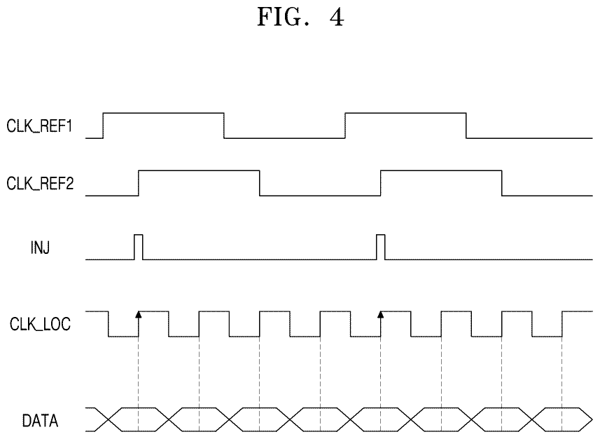

FIG. 3 is a block diagram of the receiver 140 according to an example embodiment. FIG. 4 is a timing diagram showing signals according to an example embodiment. FIGS. 3 and 4 may be described with reference to FIGS. 1 and 2, and repeated descriptions thereof may be omitted.

Referring to FIG. 3, the receiver 140 may include the clock generator 150 and the CDR circuit 160.

The clock generator 150 may include a Digital-to-Time Converter (DTC) 151, a pulse generator 152, an oscillator 153, a DTC control circuit 154, a phase detector 155, and an injection polarity detector 156.

The DTC 151 may adjust the phase of the first reference clock signal CLK_REF1 based on DTC code DTC_CD received from the DTC control circuit 154, thus outputting a second reference clock signal CLK_REF2. As shown in FIG. 4, the second reference clock signal CLK_REF2 and the first reference clock signal CLK_REF1 may have the same frequency but different phases. The DTC 151 may provide the second reference clock signal CLK_REF2 to the pulse generator 152, the phase detector 155, and the injection polarity detector 156.

In an example embodiment, the DTC code DTC_CD may be less than the maximum bound reference code and greater than the minimum bound reference code.

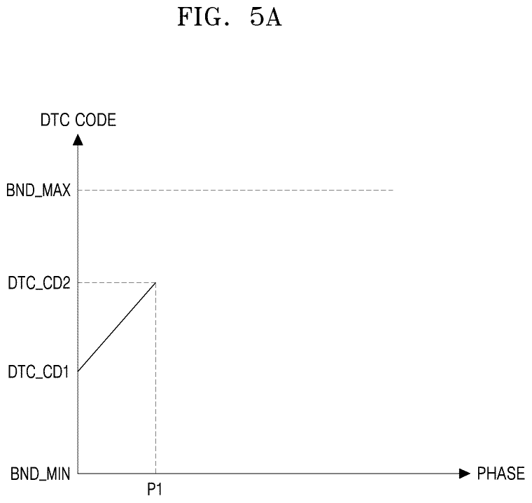

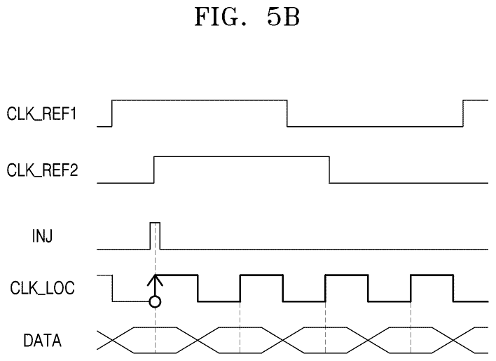

In an example embodiment, the DTC 151 may advance or delay the phase of the second reference clock signal CLK_REF2 based on the value indicated by the DTC code DTC_CD. This is described below with reference to FIGS. 5A to 7B.

The pulse generator 152 may periodically generate an injection signal INJ based on the second reference clock signal CLK_REF2. The injection signal INJ may be output from an edge of the second reference clock signal CLK_REF2. The injection signal INJ may be applied to a switch 153_1 included in the oscillator 153, thus synchronizing the phase of the local clock signal CLK_LOC with that of the second reference clock signal CLK_REF2.

In an example embodiment, referring to FIG. 4, the injection signal INJ may be a signal that is output from a rising edge of the second reference clock signal CLK_REF2, but this is only an example. The injection signal INJ may be a signal that is output from a falling edge of the second reference clock signal CLK_REF2.

The pulse generator 152 may not generate the injection signal INJ because of a pulse gating signal P_GAT received from a rollover logic circuit 154_1.

In an example embodiment, the pulse generator 152 may not generate the injection signal INJ during one period of the second reference clock signal CLK_REF2 due to the pulse gating signal P_GAT received from the rollover logic circuit 154_1.

The oscillator 153 may include the switch 153_1. The oscillator 153 may generate the local clock signal CLK_LOC. In response to the injection signal INJ, the oscillator 153 may synchronize the phase of the second reference clock signal CLK_REF2 with the phase of the local clock signal CLK_LOC. In other words, the switch 153_1 may be turned on or off in response to the injection signal INJ, and the oscillator 153 may adjust the phase of the local clock signal CLK_LOC based on the on/off operation of the switch 153_1. The adjustment of the local clock signal CLK_LOC may be conducted to sample the data DATA at the correct timing. In the present specification, the synchronization of any two signals may refer to aligning the phases of the two signals. For example, the synchronization of the phase of the second reference clock signal CLK_REF2 with the phase of the local clock signal CLK_LOC may include ensuring that the local lock signal CLK_LOC also has a rising edge at the rising edge of the second reference clock signal CLK_REF2. In addition, for example, the synchronization of the phase of the second reference clock signal CLK_REF2 with that of the local clock signal CLK_LOC may include ensuring that the local clock signal CLK_LOC has a rising edge at the falling edge of the second reference clock signal CLK_REF2.

In an example embodiment, as shown in FIG. 4, the oscillator 153 may adjust the phase of the local clock signal CLK_LOC to ensure that the local clock signal CLK_LOC has a rising edge at the edge (e.g., the rising edge) of the second reference clock signal CLK_REF2.

In an example embodiment, the oscillator 153 may adjust the phase of the local clock signal CLK_LOC to ensure that the local clock signal CLK_LOC has the falling edge at the edge (e.g., the rising edge) of the second reference clock signal CLK_REF2.

The DTC control circuit 154 may include the rollover logic circuit 154_1, an accumulator 154_2, and a multiplexer 154_3.

The rollover logic circuit 154_1 may be configured to store rollover code RO_CD and may increase or decrease the rollover code RO_CD based on a phase error value PH_ERR.

When the clock generator 150 operates in an estimation mode, the rollover logic circuit 154_1 may output, as estimation code, the result of adding the phase code PH_CD provided from the accumulator 154_2 to the rollover code RO_CD. In addition, when the clock generator 150 operates in the estimation mode, the rollover logic circuit 154_1 may control the multiplexer 154_3 to output the estimation code EST_CD as the DTC code DTC_CD in response to a selection signal SEL.

When the clock generator 150 operates in a normal mode, the rollover logic circuit 154_1 may control the multiplexer 154_3 to output the phase code PH_CD as the DTC code DTC_CD, in response to the selection signal SEL.

In addition, the rollover logic circuit 154_1 may perform a rollover operation in response to the DTC code DTC_CD matching the bound reference code. Performing the rollover operation by the rollover logic circuit 154_1 may indicate that the rollover code RO_CD stored in the rollover logic circuit 154_1 is provided to the accumulator 154_2 at the point in time when the DTC code DTC_CD matches the bound reference code. When the rollover operation is performed, the edge state of the local clock signal CLK_LOC synchronized with the second reference clock signal CLK_REF2 may be reversed by the injection signal INJ. For example, when the injection signal INJ is applied to the switch 153_1 before the rollover operation is performed by the rollover logic circuit 154_1, it is assumed that the edge of the local clock signal CLK_LOC, which is synchronized with the edge of the second reference clock signal CLK_REF2, is the rising edge. In this case, when the rollover operation is performed by the rollover logic circuit 154_1, the edge of the local clock signal CLK_LOC, which is synchronized with the edge of the second reference clock signal CLK_REF2 when the injection signal INJ is applied to the switch 153_1, may be changed to the falling edge.

In an example embodiment, it is assumed that the timing of the data DATA received from the second device 200 is slightly delayed over time. In this case, the DTC control circuit 154 may adjust the phase of the local clock signal CLK_LOC for sampling the data DATA by delaying the second reference clock signal CLK_REF2. The delay of the second reference clock signal CLK_REF2 may refer to the delay of the phase of the second reference clock signal CLK_REF2 and may be achieved by increasing the DTC code DTC_CD. When the DTC code DTC_CD continues to increase, the DTC code DTC_CD may reach the bound reference code. In the present specification, the bound reference code, which is the upper limit of the DTC code DTC_CD, may be referred to as the maximum bound reference code.

In an example embodiment, it is assumed that the timing of the data DATA received from the second device 200 is slightly advanced over time. In this case, the DTC control circuit 154 may adjust the phase of the local clock signal CLK_LOC for sampling the data DATA by advancing the second reference clock signal CLK_REF2. Advancing the second reference clock signal CLK_REF2 may refer to advancing the phase of the second reference clock signal CLK_REF2 and may be achieved by reducing the DTC code DTC_CD. When the DTC code DTC_CD continues to decrease, the DTC code DTC_CD may reach the bound reference code. In the present specification, the bound reference code, which is the lower limit of the DTC code DTC_CD, may be referred to as the minimum bound reference code.

The rollover logic circuit 154_1 provides the selection signal SEL to the multiplexer 154_3, thereby controlling the multiplexer 154_3 to select either the phase code PH_CD or the estimation code EST_CD and to output the selected code as the DTC code DTC_CD.

The clock generator 150 may basically operate in the normal mode and periodically operate in the estimation mode. When the clock generator 150 operates in the estimation mode, the rollover logic circuit 154_1 may generate the selection signal SEL for allowing the multiplexer 154_3 to output the estimation code EST_CD as the DTC code DTC_CD and also generate the pulse gating signal P_GAT, thus controlling the pulse generator 152 not to generate the injection signal INJ.

The period during which the clock generator 150 operates in the estimation mode may be greater than the period of the second reference clock signal CLK_REF2. As the clock generator 150 according to an example embodiment intermittently operates in the estimation mode, the first device 100a may reduce the power consumed to generate the local clock signal CLK_LOC and correct the phase.

In an example embodiment, when the DTC code DTC_CD is greater than first estimation reference code, the clock generator 150 may operate in a coarse estimation mode. The period of the operation in the coarse estimation mode may be greater than that of the second reference clock signal CLK_REF2. For example, the period, during which the clock generator 150 operates in the coarse estimation mode, may be 32 times the period of the second reference clock signal CLK_REF2. However, this is only an example and is not intended to limit the inventive concept.

In an example embodiment, when the DTC code DTC_CD is greater than second estimation reference code, the clock generator 150 may operate in a fine estimation mode. In this case, the second estimation reference code may be greater than the first estimation reference code. The period of the operation in the fine estimation mode may be greater than the second reference clock signal CLK_REF2 and less than the period of the operation in the coarse estimation mode. For example, the period, during which the clock generator 150 operates in the fine estimation mode, may be 8 times the period of the second reference clock signal CLK_REF2. However, this is only an example and is not intended to limit the inventive concept.

When the clock generator 150 finishes operating in the estimation mode, the clock generator 150 may resume operating in the normal mode. When the clock generator 150 operates in the normal mode, the rollover logic circuit 154_1 may generate the selection signal SEL for outputting the phase code PH_CD as the DTC code DTC_CD and may not generate the pulse gating signal P_GAT. In other words, the injection signal INJ generated by the pulse generator 152 may not be gated.

The accumulator 154_2 may cumulatively calculate the value represented by the phase information PINF received from the CDR circuit 160 and provide the calculated value to the multiplexer 154_3 as the phase code PH_CD.

The accumulator 154_2 may provide the phase code PH_CD to the multiplexer 154_3 and the rollover logic circuit 154_1. When the rollover logic circuit 154_1 performs the rollover operation, the accumulator 154_2 may receive the rollover code RO_CD from the rollover logic circuit 154_1 and further accumulate the rollover code RO_CD to the value already accumulated in the accumulator 154_2, thereby providing the calculated rollover target code ROT_CD to the multiplexer 154_3 as the phase code PH_CD.

The multiplexer 154_3 may output a selected one of the phase code PH_CD and the estimation code EST_CD as the DTC code DTC_CD, based on the selection signal SEL received from the rollover logic circuit 154_1, and provide the selected code to the DTC 151.

When the clock generator 150 operates in the estimation mode, the phase detector 155 may generate the phase error value PH_ERR based on the phase difference between the second reference clock signal CLK_REF2 and the local clock signal CLK_LOC.

In an example embodiment, when the phase of the second reference clock signal CLK_REF2, which is adjusted based on the estimation code EST_CD, is delayed compared to the phase of the local clock signal CLK_LOC, the phase detector 155 may output a phase error value PH_ERR having a first error value. In response to the phase error value PH_ERR being the first error value (e.g., “0”), the rollover logic circuit 154_1 may increase the value of the rollover code RO_CD.

In an example embodiment, when the phase of the second reference clock signal CLK_REF2, which is adjusted based on the estimation code EST_CD, is advanced compared to the phase of the local clock signal CLK_LOC, the phase detector 155 may output a phase error value PH_ERR having a second error value. In response to the phase error value PH_ERR being the second error value (e.g., “1”), the rollover logic circuit 154_1 may decrease the value of the rollover code RO_CD.

In an example embodiment, when the clock generator 150 operates in the coarse estimation mode, the unit by which the rollover logic circuit 154_1 increases or decreases the value of the estimation code EST_CD may be a first value (e.g., 2 bits).

In an example embodiment, when the clock generator 150 operates in the fine estimation mode, the unit by which the rollover logic circuit 154_1 increases or decreases the value of the estimation code EST_CD may be a second value. In this case, the second value (e.g., one bit) may be less than the first value.

The injection polarity detector 156 may detect the edge state of the local clock signal CLK_LOC synchronized with the injection signal INJ, based on the second reference clock signal CLK_REF2 and the local clock signal CLK_LOC.

In an example embodiment, in the case where the edge of the local clock signal CLK_LOC is a rising edge when the injection signal INJ is applied to the oscillator 153, the injection polarity detector 156 may output a first polarity value (e.g., “0”).

In an example embodiment, in the case where the edge of the local clock signal CLK_LOC is a falling edge when the injection signal INJ is applied to the oscillator 153, the injection polarity detector 156 may output a first polarity value (e.g., “1”).

FIGS. 5A to 7B illustrate changes in DTC code and corresponding timing diagrams according to the operation of the receiver 140, according to an example embodiment. FIGS. 5A to 7B may be described with reference to FIGS. 1 to 4, and repeated descriptions thereof may be omitted.

In FIGS. 5A to 7B, it is assumed that the clock generator 150 operates in the normal mode. In addition, due to jitters occurring during the transmission of signals to the receiver 140, it is assumed that the data DATA is delayed compared to ideal situations.

To allow the CDR circuit 160 to sample the data DATA at the correct timing, there may be a need for the local clock signal CLK_LOC with a phase corresponding to the timing of the data DATA. FIGS. 5A to 7B illustrate a series of operations of adjusting the phase of the second reference clock signal CLK_REF2 by increasing or decreasing the DTC code DTC_CD to adjust the phase of the local clock signal CLK_LOC.

In addition, in FIGS. 5A, 6A, and 7A, each horizontal axis indicates the phase of the second reference clock signal CLK_REF2 delayed (or advanced), and each vertical axis represents the value of the DTC code DTC_CD applied to the DTC 151.

Referring to FIGS. 5A and 5B, it is assumed that, when first DTC code DTC_CD1 is provided to the DTC 151, the delayed phase of the second reference clock signal CLK_REF2 is 0, and when second DTC code DTC_CD2 is provided to the DTC 151, the delayed phase of the second reference clock signal CLK_REF2 is P1.

When the data DATA provided to the CDR circuit 160 is delayed, if the phase of the local clock signal CLK_LOC is further delayed, the CDR circuit 160 may sample the data DATA at the correct timing. The CDR circuit 160 may output the phase information PINF with the first phase value (e.g., “1”) to further delay the phase of the local clock signal CLK_LOC. By delaying the phase of the second reference clock signal CLK_REF2 from 0 to P1, the injection signal INJ is applied to the oscillator 153 at the rising edge of the delayed second reference clock signal CLK_REF2, and as shown in FIG. 5B, the oscillator 153 may generate the local clock signal CLK_LOC synchronized to have a rising edge at the rising edge of the delayed second reference clock signal CLK_REF2. The CDR circuit 160 may sample the data DATA at the rising edge of the local clock signal CLK_LOC with the adjusted phase.

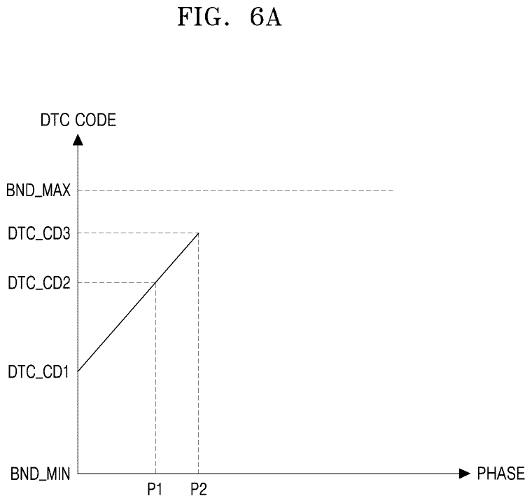

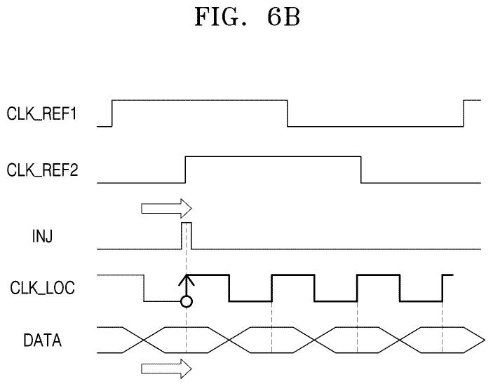

FIGS. 6A and 6B are diagrams illustrating that the phase of the second reference clock signal CLK_REF2 is adjusted when the data DATA is further delayed, compared to the case shown in FIGS. 5A and 5B. It is assumed that, when the phase of the second reference clock signal CLK_REF2 is adjusted to P2, the local clock signal CLK_LOC may sample the data DATA at the correct timing.

Referring to FIGS. 6A and 6B, when third DTC code DTC_CD3 is provided to the DTC 151, it is assumed that the delayed phase of the second reference clock signal CLK_REF2 is P2.

By delaying the phase of the second reference clock signal CLK_REF2 from P1 to P2, the injection signal INJ may be applied to the oscillator 153 at the delayed rising edge of the second reference clock signal CLK_REF2, and the oscillator 153 may generate the local clock signal CLK_LOC synchronized to have a rising edge at the delayed rising edge of the second reference clock signal CLK_REF2. The CDR circuit 160 may sample the data DATA at the rising edge of the local clock signal CLK_LOC with the adjusted phase.

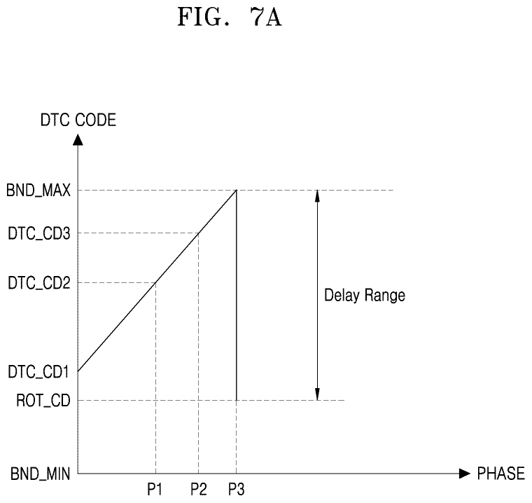

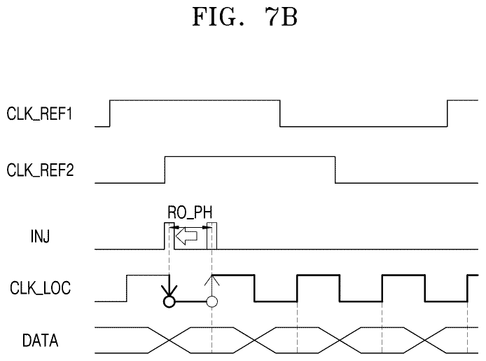

FIGS. 7A and 7B are diagrams illustrating that the phase of the second reference clock signal CLK_REF2 is adjusted when the data DATA is further delayed, compared to the case shown in FIGS. 6A and 6B. It is assumed that, when the phase of the second reference clock signal CLK_REF2 is adjusted to P3, the local clock signal CLK_LOC may sample the data DATA at the correct timing.

Referring to FIGS. 7A and 7B, when the DTC code DTC_CD matches the maximum bound reference code BND_MAX, the DTC code DTC_CD is less than the maximum bound reference code BND_MAX, and thus, the rollover logic circuit 154_1 may perform the rollover operation.

The rollover logic circuit 154_1 may provide the accumulator 154_2 with the rollover code RO_CD acquired through the estimation operations having been performed before the rollover operation is performed, and the accumulator 154_2 may accumulate the received rollover code RO_CD to the value already stored in the accumulator 154_2 and output the result. In this case, the result that is output by the accumulator 154_2 may correspond to the rollover target code ROT_CD.

Based on the rollover target code ROT_CD, the DTC 151 may adjust the phase of the second reference clock signal CLK_REF2.

When the rollover operation is performed by the rollover logic circuit 154_1, the edge state of the local clock signal CLK_LOC, which is synchronized with the edge of the second reference clock signal CLK_REF2, may be reversed. For example, referring to FIG. 7B (after the rollover operation), unlike the case where the rising edge of the local clock signal CLK_LOC is synchronized with the rising edge of the second reference clock signal CLK_REF2 as shown in FIGS. 5B and 6B (before the rollover operation), the falling edge of the local clock signal CLK_LOC may be synchronized with the rising edge of the second reference clock signal CLK_REF2. Even in this case, the timing at which the CDR circuit 160 samples the data DATA based on the local clock signal CLK_LOC may still be at the rising edge of the local clock signal CLK_LOC.

After the rollover operation, the phase of the second reference clock signal CLK_REF2 may be advanced by the rollover phase RO_PH from P3, which may result in the same phase as when the second reference clock signal CLK_REF2 is at P3.

In the present specification, the rollover phase RO_PH may refer to a phase value corresponding to half of the period of the local clock signal CLK_LOC and may represent a value corresponding to a delay range.

In the present specification, the delay range may refer to the difference between the bound reference code and the rollover target code ROT_CD.

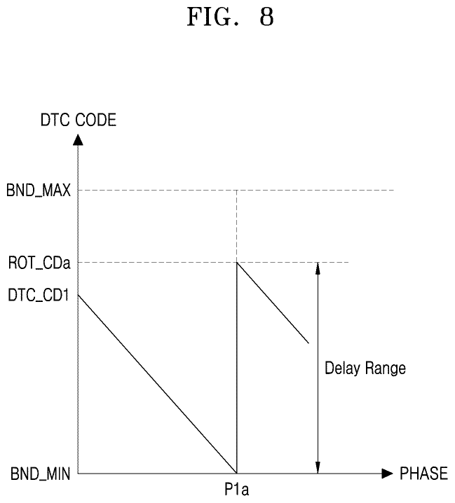

FIG. 8 illustrates a change in the DTC code DTC_CD according to the operation of the receiver 140, according to an example embodiment. FIG. 8 may be described with reference to FIGS. 1 to 7B, and repeated descriptions thereof may be omitted.

FIG. 8 is a diagram illustrating a situation in which, unlike FIGS. 5A to 7B, the DTC code DTC_CD needs to be reduced as the data DATA received by the CDR circuit 160 has a faster timing than in ideal situations.

Referring to FIG. 8, there may be a need for a local clock signal CLK_LOC with a phase corresponding to the timing of the data DATA to allow the CDR circuit 160 to sample the data DATA at the correct timing, as shown in FIGS. 5A to 7B.

In the case where the phase of the local clock signal CLK_LOC is advanced when the timing of the data DATA provided to the CDR circuit 160 becomes faster, the CDR circuit 160 may sample the data DATA at the correct timing. The CDR circuit 160 may output the second phase value as the phase information PINF to further advance the phase of the local clock signal CLK_LOC.

By advancing the phase of the second reference clock signal CLK_REF2, the injection signal INJ may be applied to the oscillator 153 at the rising edge of the advanced second reference clock signal CLK_REF2, and the oscillator 153 may generate the local clock signal CLK_LOC synchronized to have a rising edge at the delayed rising edge of the delayed second reference clock signal CLK_REF2. The CDR circuit 160 may sample the data DATA at the rising edge of the local clock signal CLK_LOC with the adjusted phase.

When the DTC code DTC_CD matches the minimum bound reference code BND_MIN according to the result of the reduction in the DTC code DTC_CD, the rollover operation may be performed by the rollover logic circuit 154_1.

The rollover logic circuit 154_1 may provide the accumulator 154_2 with the rollover code RO_CD obtained through the estimation operations performed before the rollover operation, and the accumulator 154_2 may accumulate the received rollover code RO_CD to the value already stored in the accumulator 154_2 and output the result. In this case, the result that is output from the accumulator 154_2 may correspond to a rollover target code ROT_CDa.

After the rollover operation, the phase of the second reference clock signal CLK_REF2 may be delayed from Pla by the rollover phase, which may result in the same phase as when the second reference clock signal CLK_REF2 is at Pla.

In an example embodiment, when the DTC code DTC_CD is less than the first estimation reference code, the clock generator 150 may operate in the coarse estimation mode. The period of the operation in the coarse estimation mode may be greater than that of the second reference clock signal CLK_REF2. For example, the period, during which the clock generator 150 operates in the coarse estimation mode, may be 32 times the period of the second reference clock signal CLK_REF2. However, this is only an example and is not intended to limit the inventive concept.

In an example embodiment, when the DTC code DTC_CD is less than the second estimation reference code, the clock generator 150 may operate in the fine estimation mode. In this case, the second estimation reference code may be less than the first estimation reference code. The period of the operation in the fine estimation mode may be greater than the second reference clock signal CLK_REF2 and less than the period of the operation in the coarse estimation mode. For example, the period, during which the clock generator 150 operates in the fine estimation mode, may be 8 times the period of the second reference clock signal CLK_REF2. However, this is only an example and is not intended to limit the inventive concept.

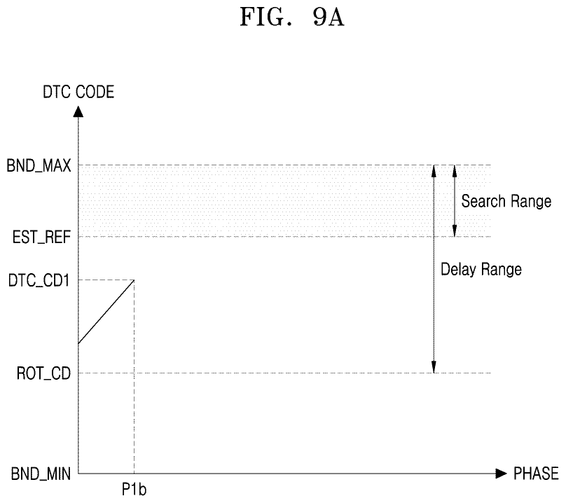

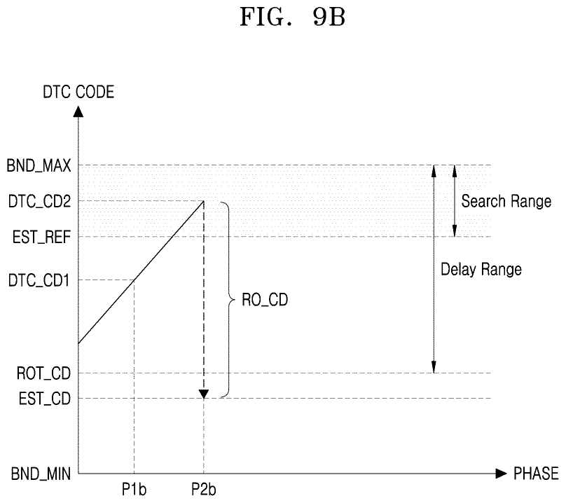

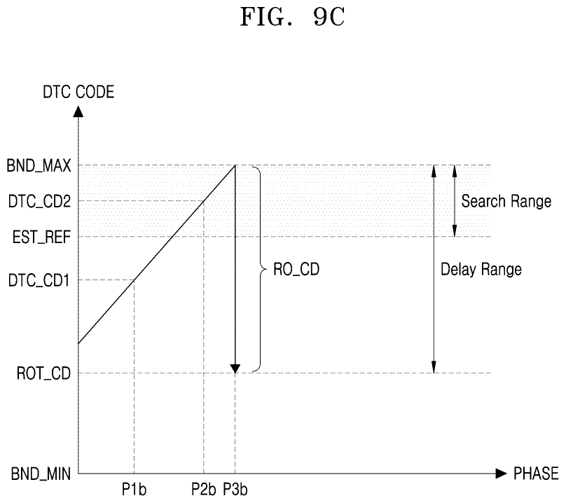

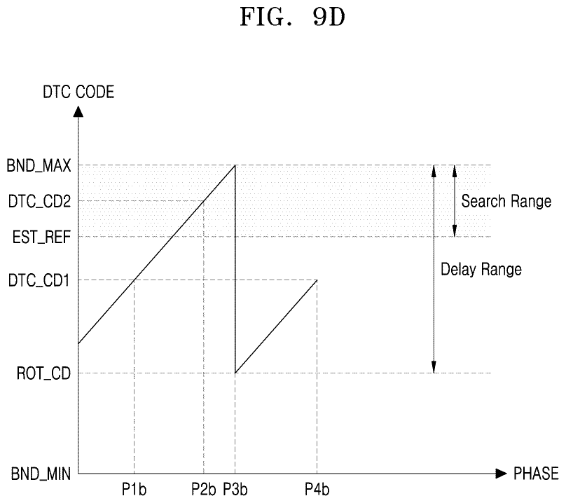

FIGS. 9A to 9D are graphs for describing an operation of a clock generator, according to an example embodiment. FIGS. 9A to 9D may be described with reference to FIGS. 1 to 7B, and repeated descriptions thereof may be omitted.

FIGS. 9A to 9D illustrate a search range as a region adjacent to the maximum bound reference code BND_MAX, but one or more example embodiments are not limited thereto. In an example embodiment (e.g., the example embodiment shown in FIG. 8) in which the DTC code DTC_CD decreases, the search range may be a region that is adjacent to the minimum bound reference code BND_MIN. For convenience of explanation, FIGS. 9A to 9D are described based on the example embodiment in which the DTC code DTC_CD increases.

In the present specification, the search range may refer to the range of the DTC code DTC_CD in which the clock generator 150 operates in the estimation mode.

Referring to FIG. 9A, it is assumed that the DTC code DTC_CD provided to the DTC 151 is the first DTC code DTC_CD1 configured to delay the phase of the second reference clock signal CLK_REF2 by P1b. In this case, because the DTC code DTC_CD provided to the DTC 151 is less than estimation reference code EST_REF, the clock generator 150 may operate in the normal mode. In some example embodiments, the normal mode may be referred to as a phase tracking mode.

Referring to FIG. 9B, it is assumed that the DTC code DTC_CD provided to the DTC 151 is the second DTC code DTC_CD2 configured to delay the phase of the second reference clock signal CLK_REF2 by P2b. In this case, because the DTC code DTC_CD provided to the DTC 151 is greater than the estimation reference code EST_REF but less than the maximum bound reference code BND_MAX, the clock generator 150 may periodically operate in the estimation mode.

In an example embodiment, the estimation reference code EST_REF may be classified into a first estimation reference code and a second estimation reference code. The first estimation reference code may be a code that is the reference for the clock generator 150 to operate in the coarse estimation mode. The second estimation reference code may be a code that is the reference for the clock generator 150 to operate in the fine estimation mode. The second estimation reference code may have a value between the first estimation reference code and the bound reference code. For example, the first estimation reference code may correspond to the estimation reference code EST_REF, and the second estimation reference code may be a code having a value between the estimation reference code EST_REF and the maximum bound reference code BND_MAX.

In an example embodiment, the rollover code RO_CD may be a code stored in the rollover logic circuit 154_1. When the rollover logic circuit 154_1 initially performs an estimation operation, the value stored in advance in the rollover logic circuit 154_1 may be used as the rollover code RO_CD. The rollover code RO_CD may have a positive value or a negative value depending on the rollover direction. As shown in FIG. 9B, for example, when the rollover operation is performed in the direction in which the DTC code DTC_CD decreases, the sign of the rollover code RO_CD may be negative. On the contrary, when the rollover operation is performed in the direction in which the DTC code DTC_CD increases, the sign of the rollover code RO_CD may be positive.

In an example embodiment, the rollover logic circuit 154_1 may control the multiplexer 154_3 to output the estimation code EST_CD as the DTC code DTC_CD. The DTC 151 may adjust the phase of the second reference clock signal CLK_REF2 based on the estimation code EST_CD received as the DTC code DTC_CD. When the clock generator 150 operates in the estimation mode, the rollover logic circuit 154_1 may correct the rollover code RO_CD by decreasing or increasing, based on the phase error value PH_ERR received from the phase detector 155, the rollover code RO_CD to make the value of the estimation code EST_CD close to the rollover target code ROT_CD.

Referring to FIG. 9C, it is assumed that the DTC code DTC_CD provided to the DTC 151 has the same value as the maximum bound reference code BND_MAX that delays the phase of the second reference clock signal CLK_REF2 by P3b. In this case, because the DTC code DTC_CD provided to the DTC 151 is the same as the maximum bound reference code BND_MAX, the rollover logic circuit 154_1 may perform the rollover operation. In this case, the rollover logic circuit 154_1 may provide the rollover code RO_CD to the accumulator 154_2, and the value of the rollover code RO_CD provided by the rollover logic circuit 154_1 to the accumulator 154_2 may be the same as or similar to the rollover target code ROT_CD, as shown in FIG. 9C.

Referring to FIG. 9D, it is assumed that the DTC code DTC_CD provided to the DTC 151 is the first DTC code DTC_CD1 configured to delay the phase of the second reference clock signal CLK_REF2 by P4b. Because the DTC code DTC_CD provided to the DTC 151 is less than the estimation reference code EST_REF, the clock generator 150 may operate in the normal mode. In an example embodiment, the phase difference between P1b and P4b may correspond to half the period of the local clock signal CLK_LOC.

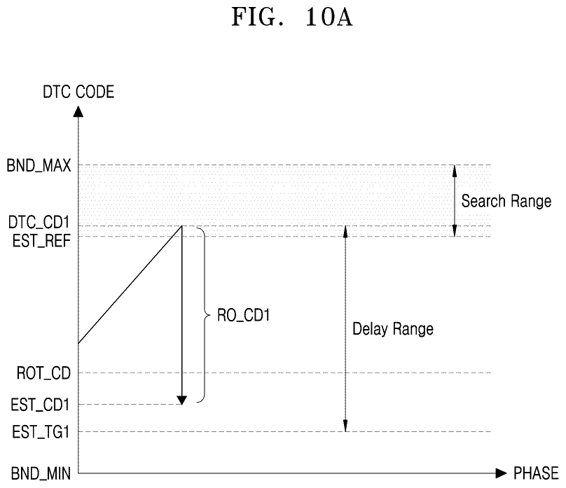

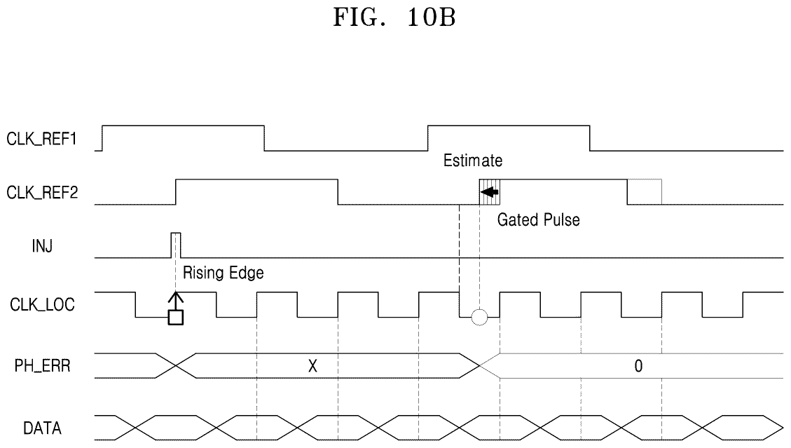

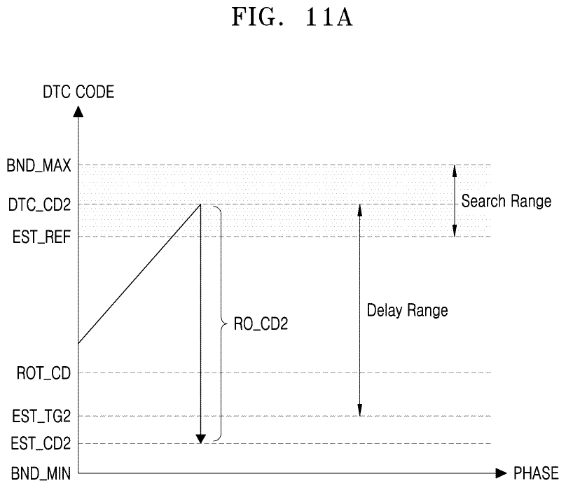

FIGS. 10A to 12B are graphs for explaining an operation of the clock generator 150, according to an example embodiment. In detail, FIGS. 10A to 12B illustrate that the clock generator 150 operates in the estimation mode. FIGS. 10A to 12B may be described with reference to FIGS. 1 to 7B, and repeated descriptions thereof may be omitted.

FIGS. 10A and 10B are diagrams for describing the example embodiment in which the phase error value PH_ERR, which is the output from the phase detector 155, is the first error value (e.g., “0”) and the rollover code RO_CD increases according to the first error value. In FIGS. 10A and 10B, it is assumed that the clock generator 150 operates in the coarse estimation mode. It is assumed that the DTC code DTC_CD provided to the DTC 151 before the operation in the estimation mode is the first DTC code DTC_CD1. The first DTC code DTC_CD1 may be the phase code PH_CD output from the accumulator 154_2.

The rollover logic circuit 154_1 may provide the first estimation code EST_CD1 to the multiplexer 154_3 as the estimation code EST_CD. In this case, because of the selection signal SEL from the rollover logic circuit 154_1, the output from the multiplexer 154_3 may be the first estimation code EST_CD1 instead of the phase code PH_CD.

In an example embodiment, at the point in time when the clock generator 150 operates in the estimation mode, the first estimation code EST_CD1 may be the value obtained by adding the rollover code RO_CD, which is stored in the rollover logic circuit 154_1, to the phase code PH_CD provided from the accumulator 154_2. In this case, the rollover code RO_CD stored in the rollover logic circuit 154_1 may be the first rollover code RO_CD1.

In an example embodiment, the difference between the first DTC code DTC_CD1 and the first estimation target code EST_TG1 may correspond to the difference between the maximum bound reference code BND_MAX and the rollover target code ROT_CD. In other words, the difference between the first DTC code DTC_CD1 and the first estimation target code EST_TG1 may correspond to the delay range.

As shown in FIG. 10A, because the value of the first estimation code EST_CD1 is greater than the first estimation target code EST_TG1, when the rollover logic circuit 154_1 performs the rollover operation based on the first estimation code EST_CD1, the phase error value PH_ERR, which is the output from the phase detector 155, may be the first error value (e.g., “0”).

Referring to FIG. 10B, when the clock generator 150 operates in the normal mode, the rising edge of the second reference clock signal CLK_REF2 may be synchronized with the rising edge of the local clock signal CLK_LOC. When the clock generator 150 operates in the estimation mode, the rising edge of the second reference clock signal CLK_REF2 may be synchronized with the falling edge of the local clock signal CLK_LOC.

Although the DTC 151 adjusts the phase of the second reference clock signal CLK_REF2 based on the first estimation code EST_CD1, the phase of the second reference clock signal CLK_REF2 needs to be further advanced to synchronize the rising edge of the second reference clock signal CLK_REF2 with the falling edge of the local clock signal CLK_LOC. The rollover logic circuit 154_1 may increase the rollover code RO_CD to be greater than the first rollover code RO_CD1 based on the phase error value PH_ERR. Here, the increase of the rollover code RO_CD may refer to the increase of the size of the value corresponding to the rollover code RO_CD.

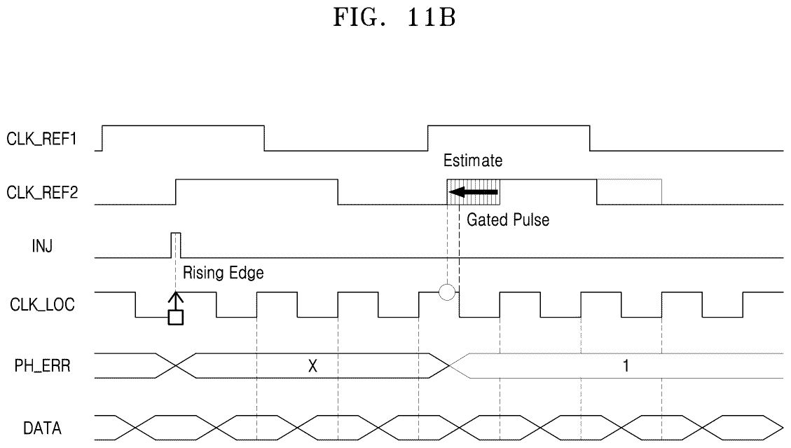

FIGS. 11A and 11B are diagrams for describing the example embodiment in which the phase error value PH_ERR, which is the output from the phase detector 155, is the second error value (e.g., “1”) and the rollover code RO_CD decreases according to the second error value. In FIGS. 11A and 11B, it is assumed that the clock generator 150 operates in the coarse estimation mode. It is assumed that the DTC code DTC_CD provided to the DTC 151 before the operation in the estimation mode is the second DTC code DTC_CD2. The second DTC code DTC_CD2 may be the phase code PH_CD output from the accumulator 154_2.

The rollover logic circuit 154_1 may provide the second estimation code EST_CD2 to the multiplexer 154_3 as the estimation code EST_CD. In this case, because of the selection signal SEL from the rollover logic circuit 154_1, the output from the multiplexer 154_3 may be the second estimation code EST_CD2 instead of the phase code PH_CD.

In an example embodiment, at the point in time when the clock generator 150 operates in the estimation mode, the second estimation code EST_CD2 may be the value obtained by adding the rollover code RO_CD, which is stored in the rollover logic circuit 154_1, to the phase code PH_CD provided from the accumulator 154_2. In this case, the rollover code RO_CD stored in the rollover logic circuit 154_1 may be the second rollover code RO_CD2, and the second rollover code RO_CD2 may be obtained by increasing the first rollover code RO_CD1 by the first value.

In an example embodiment, the difference between the second DTC code DTC_CD2 and second estimation target code EST_TG2 may correspond to the difference between the maximum bound reference code BND_MAX and the rollover target code ROT_CD. In other words, the difference between the second DTC code DTC_CD2 and the second estimation target code EST_TG2 may correspond to the delay range.

As shown in FIG. 11A, because the value of the second estimation code EST_CD2 is less than the second estimation target code EST_TG2, when the rollover logic circuit 154_1 performs the rollover operation based on the second estimation code EST_CD2, the phase error value PH_ERR, which is the output from the phase detector 155, may be the second error value (e.g., “1”).

Referring to FIG. 11B, although the DTC 151 adjusts the phase of the second reference clock signal CLK_REF2 based on the second estimation code EST_CD2, the phase of the second reference clock signal CLK_REF2 needs to be further delayed to synchronize the rising edge of the second reference clock signal CLK_REF2 with the falling edge of the local clock signal CLK_LOC. The rollover logic circuit 154_1 may decrease the rollover code RO_CD to be less than the second rollover code RO_CD2 based on the phase error value PH_ERR. Here, the decrease of the rollover code RO_CD may refer to the decrease of the size of the value corresponding to the rollover code RO_CD.

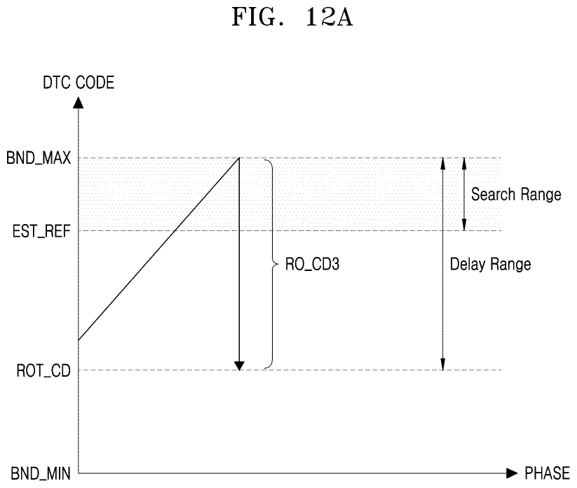

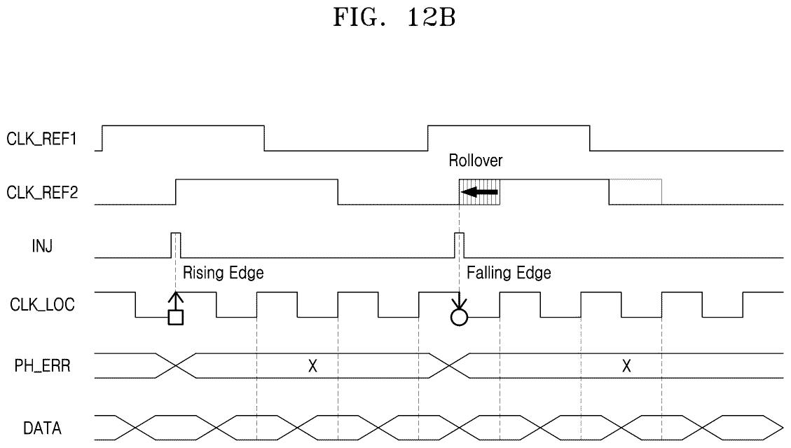

FIGS. 12A and 12B are diagrams for explaining the example embodiment in which, when the DTC code DTC_CD provided to the DTC 151 matches the maximum bound reference code BND_MAX, the rollover logic circuit 154_1 performs a rollover operation.

The rollover logic circuit 154_1 may provide a third rollover code RO_CD3 to the accumulator 154_2. The third rollover code RO_CD3 may be a code stored in the rollover logic circuit 154_1 and may be obtained by increasing the second rollover code RO_CD2 by the first value.

In an example embodiment, the difference between the maximum bound reference code BND_MAX and the rollover target code ROT_CD may correspond to the third rollover code RO_CD3.

Referring to FIG. 12B, the accumulator 154_2 may accumulate the third rollover code RO_CD3, which is received from the rollover logic circuit 154_1, to the value already stored in the accumulator 154_2, thereby providing an accumulated result to the multiplexer 154_3 as the phase code PH_CD. In this case, the local clock signal CLK_LOC may have a falling edge at the rising edge of the second reference clock signal CLK_REF2.

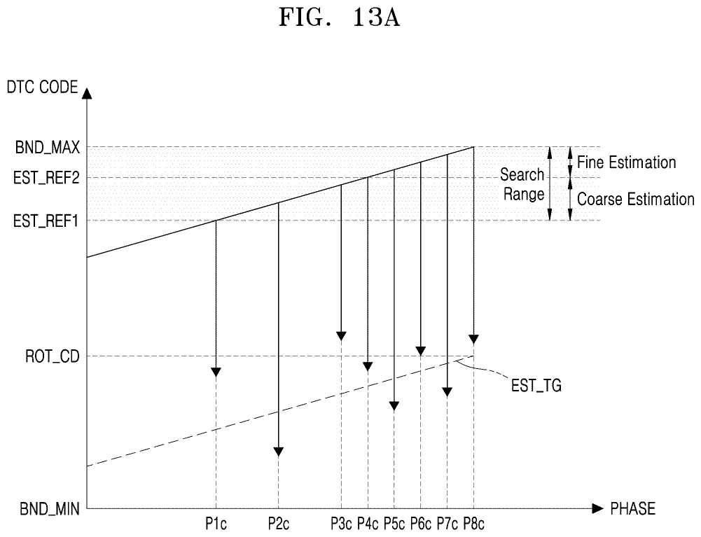

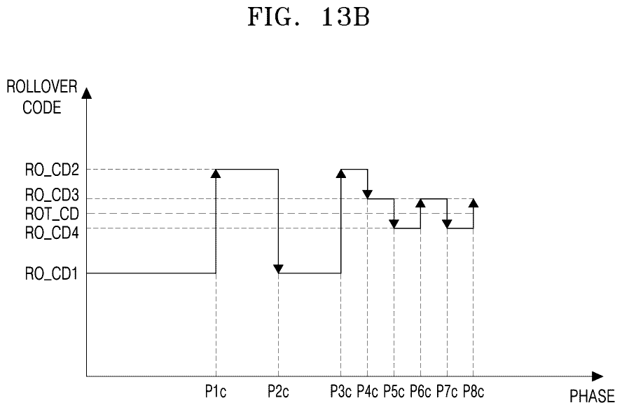

FIGS. 13A and 13B are graphs showing an estimation mode according to an example embodiment. FIGS. 13A and 13B may be described with reference to FIGS. 1 to 7B, and repeated descriptions thereof may be omitted.

FIGS. 13A and 13B are diagrams for explaining a series of operations of searching for a rollover target code ROT_CD by correcting the rollover code RO_CD by increasing or decreasing the same according to the change in the DTC code DTC_CD. It is assumed that the clock generator 150 periodically operates in the estimation mode.

In FIG. 13A, the long dashed line indicates the estimation target code EST_TG changing according to the change in the DTC code DTC_CD. The difference between the DTC code DTC_CD and the estimation target code EST_TG may correspond to the delay range. In addition, at each phase, the value of the estimation code EST_CD may be the sum of the DTC code DTC_CD and the rollover code RO_CD.

First of all, FIG. 13A illustrates the case where the phase of the second reference clock signal CLK_REF2 delayed by the DTC 151 ranges from a first phase Plc to a third phase P3c. When the clock generator 150 operates in the normal mode, the DTC code DTC_CD provided to the DTC 151 may be greater than the first estimation reference code EST_REF1 and less than the second estimation reference code EST_REF2. In this case, when the clock generator 150 operates in the estimation mode, the estimation mode may be the coarse estimation mode.

Referring to FIGS. 13A and 13B, in an example embodiment, at the point in time when the phase of the second reference clock signal CLK_REF2 delayed by the DTC 151 is the first phase Plc, the clock generator 150 may perform an estimation operation by using the first rollover code RO_CD1 stored in the rollover logic circuit 154_1. As a result of performing the estimation operation, a greater rollover code RO_CD may be required to align the value of the estimation code EST_CD with the estimation target code EST_TG. The rollover logic circuit 154_1 may update the rollover code RO_CD to the second rollover code RO_CD2 by increasing the first rollover code RO_CD1 by a first value.

In an example embodiment, at the point in time when the phase of the second reference clock signal CLK_REF2 delayed by the DTC 151 is the second phase P2c, the clock generator 150 may perform an estimation operation by using the second rollover code RO_CD2 stored in the rollover logic circuit 154_1. As a result of performing the estimation operation, a smaller rollover code RO_CD may be required to align the value of the estimation code EST_CD with the estimation target code EST_TG. The rollover logic circuit 154_1 may update the rollover code RO_CD to the first rollover code RO_CD1 by decreasing the second rollover code RO_CD1 by a first value.

In an example embodiment, at the point in time when the phase of the second reference clock signal CLK_REF2 delayed by the DTC 151 is the third phase P3c, the clock generator 150 may perform an estimation operation by using the first rollover code RO_CD1 stored in the rollover logic circuit 154_1. As a result of performing the estimation operation, a greater rollover code RO_CD may be required to align the value of the estimation code EST_CD with the estimation target code EST_TG. The rollover logic circuit 154_1 may update the rollover code RO_CD to the second rollover code RO_CD2 by increasing the first rollover code RO_CD1 by a first value.

First of all, FIG. 13A illustrates the case where the phase of the second reference clock signal CLK_REF2 delayed by the DTC 151 ranges from a fourth phase P4c to an eighth phase P8c. When the clock generator 150 operates in the normal mode, the DTC code DTC_CD provided to the DTC 151 may be greater than the second estimation reference code EST_REF2 and less than the maximum bound reference code BND_MAX. In this case, when the clock generator 150 operates in the estimation mode, the estimation mode may be the fine estimation mode.

Referring to FIGS. 13A and 13B, in an example embodiment, at the point in time when the phase of the second reference clock signal CLK_REF2 delayed by the DTC 151 is the fourth phase P4c, the clock generator 150 may perform an estimation operation by using the second rollover code RO_CD2 stored in the rollover logic circuit 154_1. As a result of performing the estimation operation, a smaller rollover code RO_CD may be required to align the value of the estimation code EST_CD with the estimation target code EST_TG. The rollover logic circuit 154_1 may update the rollover code RO_CD to the third rollover code RO_CD3 by decreasing the second rollover code RO_CD2 by a second value. In this case, the second value may be less than the first value. For example, the second value may be “1,” and the first value may be “2.” However, this is only an example and is not intended to limit the inventive concept.

In an example embodiment, at the point in time when the phase of the second reference clock signal CLK_REF2 delayed by the DTC 151 is the fifth phase P5c, the clock generator 150 may perform an estimation operation by using the third rollover code RO_CD3 stored in the rollover logic circuit 154_1. As a result of performing the estimation operation, a smaller rollover code RO_CD may be required to align the value of the estimation code EST_CD with the estimation target code EST_TG. The rollover logic circuit 154_1 may update the rollover code RO_CD to the fourth rollover code RO_CD4 by decreasing the third rollover code RO_CD3 by a second value.

In an example embodiment, at the point in time when the phase of the second reference clock signal CLK_REF2 delayed by the DTC 151 is the sixth phase P6c, the clock generator 150 may perform an estimation operation by using the fourth rollover code RO_CD4 stored in the rollover logic circuit 154_1. As a result of performing the estimation operation, a greater rollover code RO_CD may be required to align the value of the estimation code EST_CD with the estimation target code EST_TG. The rollover logic circuit 154_1 may update the rollover code RO_CD to the third rollover code RO_CD3 by increasing the fourth rollover code RO_CD4 by a second value.

In an example embodiment, at the point in time when the phase of the second reference clock signal CLK_REF2 delayed by the DTC 151 is the seventh phase P7c, the clock generator 150 may perform an estimation operation by using the third rollover code RO_CD3 stored in the rollover logic circuit 154_1. As a result of performing the estimation operation, a smaller rollover code RO_CD may be required to align the value of the estimation code EST_CD with the estimation target code EST_TG. The rollover logic circuit 154_1 may update the rollover code RO_CD to the fourth rollover code RO_CD4 by decreasing the third rollover code RO_CD3 by a second value.

In an example embodiment, at the point in time when the phase of the second reference clock signal CLK_REF2 delayed by the DTC 151 is the eighth phase P8c, the clock generator 150 may perform an estimation operation by using the third rollover code RO_CD3 stored in the rollover logic circuit 154_1. As a result of performing the estimation operation, a greater rollover code RO_CD may be required to align the value of the estimation code EST_CD with the estimation target code EST_TG. The rollover logic circuit 154_1 may update the rollover code RO_CD to the third rollover code RO_CD3 by increasing the fourth rollover code RO_CD4 by a second value.

When the phase of the second reference clock signal CLK_REF2 delayed by the DTC 151 becomes greater than the eighth phase P8c during the operation of the clock generator 150 in the normal mode, the rollover logic circuit 154_1 may perform the rollover operation. In this case, by providing the accumulator 154_2 with the third rollover code RO_CD3 stored in the rollover logic circuit 154_1, the rollover operation may be performed. The third rollover code RO_CD3 may be a code that is the same as or similar to the rollover target code ROT_CD.

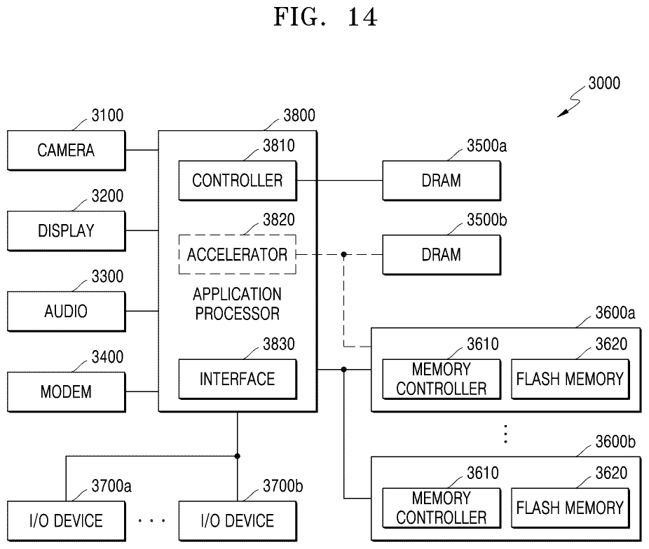

FIG. 14 is a block diagram of a system 3000 including a device, according to example embodiments.

Referring to FIG. 14, the system 3000 may include a camera 3100, a display 3200, an audio processor 3300, a modem 3400, Dynamic Random Access Memories (DRAMs) 3500a and 3600a, flash memories 3600a and 3600b, I/O devices 3700a and 3700b, and an Application Processor (AP) 3800. The system 3000 may be implemented as a laptop, a mobile phone, a smartphone, a tablet personal computer (PC), a wearable device, a healthcare device, or an Internet of Things (IoT) device. Also, the system 3000 may be implemented as a server or a PC.

The camera 3100 may capture still images or moving images under the control by the user and may store captured images or image data or transmit the same to the display 3200. The audio processor 3300 may process audio data included in content of the flash memories 3600a and 3600b or a network. The modem 3400 may modulate and transmit signals for reception/transmission of wired/wireless data and may demodulate the signals on the receiving side to restore the signals to their original signals. The I/O devices 3700a and 3700b may include devices, for example, a Universal Serial Bus (USB) or storage, a digital camera, a Secure Digital (SD) card, a Digital Versatile Disc (DVD), a network adapter, and a touch screen, which provide digital input and/or output functions.

The AP 3800 may control general operations of the system 3000. The AP 3800 may control the display 3200 such that part of the content stored in the flash memories 3600a and 3600b is displayed. When user inputs are received through the I/O devices 3700a and 3700b, the AP 3800 may perform control operations corresponding to the user inputs. The AP 3800 may include a controller 3810 and an interface 3830 and may also include an accelerator block dedicated to Artificial Intelligence (AI) data operations or an accelerator chip 3820 that is separate from the AP 3800. The DRAM 3500b may be additionally mounted on the accelerator block or the accelerator chip 3820. The accelerator is a functional block that is specialized for specific functions of the AP 3800 and may include a Graphics Processing Unit (GPU) that is specialized for graphic data processing, a Neural Processing Unit (NPU) specifically designed for AI computation and inference, and a Data Processing Unit (DPU) that is a specialized block for data transmission.

The system 3000 may include the DRAMs 3500a and 3500b. The AP 3800 may control the DRAMs 3500a and 3500b based on commands and Mode Register Set (MRS) settings complying with Joint Electron Device Engineering Council (JEDEC) standards or may communicate with the DRAMs 3500a and 3500b by setting DRAM interface protocols to utilize vendor-specific functions such as low voltage, high speed, and reliability and Cyclic Redundancy Check (CRC)/Error Correction Code (ECC) functions. For example, the AP 3800 may communicate with the DRAM 3500a by using an interface complying with JEDEC standards such as LPDDR4 or LPDDR5, and the accelerator block or the accelerator chip 3820 may establish new DRAM interface protocols to communicate with and control the DRAM 3500b for accelerators with a higher bandwidth than the DRAM 3500a.

FIG. 14 shows only two DRAMs 3500a and 3500b, but one or more example embodiments are not limited thereto. Any type of memory, such as Phase Change Random Access Memory (PRAM) or Static RAM (SRAM), Magneto-resistive RAM (MRAM), Resistive RAM (RRAM), or Ferroelectric RAM (FRAM) or Hybrid RAM, may be used as long as it meets the bandwidth, response speed, and voltage conditions required by the AP 3800 or the accelerator chip 3820. The DRAMs 3500a and 3500b may have latencies and bandwidths that are relatively lower than those of the I/O devices 3700a and 3700b or the flash memories 3600a and 3600b. The DRAMs 3500a and 3500b are initialized when the system 3000 is powered on, and the operating system and application data are loaded into the DRAMs 3500a and 3500b so that the DRAMs 3500a and 3500b may be used as temporary storage for the operating system and application data or as execution spaces for various types of software code.

In the DRAMs 3500a and 3500b, basic arithmetic operations including addition, subtraction, multiplication, and division, as well as vector operations, address operations, or Fast Fourier Transform (FFT) operations may be executed in the DRAMs 3500a and 3500b. In addition, in the DRAMs 3500a and 3500b, functions used for inference may be executed. Here, inference may be executed by a deep learning algorithm using artificial neural networks. The deep learning algorithm may include a training operation of training a model based on various types of data and an inference operation of identifying data using the trained model. In an example embodiment, images captured by the user using the camera 3100 may be signal-processed and stored in the DRAM 3500b, and the accelerator block or the accelerator chip 3820 may execute AI data operations to identify data based on the data stored in the DRAM 3500b and the functions used for inference.

The system 3000 may include a plurality of storage devices or a plurality of flash memories 3600a and 3600b with greater capacities than the DRAMs 3500a and 3500b. The accelerator block or the accelerator chip 3820 may perform the training operation and the AI data operations by using the flash memories 3600a and 3600b. In an example embodiment, the flash memories 3600a and 3600b may use a processing unit included in the memory controller 3610 to more efficiently perform the training operation and the inference AI data operations performed by the AP 3800 and/or the accelerator chip 3820. The flash memories 3600a and 3600b may store images captured by the camera 3100 or data transmitted through a data network. For example, the flash memories 3600a and 3600b may store content regarding Augmented Reality/Virtual Reality, High Definition (HD), or Ultra High Definition (UHD).

The system 3000 may transmit or receive signals for high-speed operations among components. The camera 3100, the display 3200, the audio processor 3300, the modem 3400, the DRAMs 3500a and 3500b, the flash memories 3600a and 3600b, the I/O devices 3700a and 3700b, and/or the AP 3800 in the system 3000 may include the first device 100a described with reference to FIGS. 2 to 13.

While the inventive concept has been particularly shown and described with reference to example embodiments thereof, it will be understood that various changes in form and details may be made therein without departing from the spirit and scope of the following claims.

What is claimed is:

1. A clock generator comprising:
a Digital-to-Time Converter (DTC) configured to receive a first reference clock signal from outside the clock generator, and output a second reference clock signal by adjusting a phase of the first reference clock signal based on a DTC code;
an oscillator configured to generate a local clock signal synchronized to have a rising edge at an edge of the second reference clock signal;
a phase detector configured to generate a phase error value based on a phase difference between the local clock signal and the second reference clock signal; and
a DTC control circuit configured to output the DTC code based on the phase error value and phase information received from outside the clock generator, and update the DTC code to a rollover target code in response to the DTC code matching a bound reference code; and
the oscillator being configured to adjust a phase of the second reference clock signal such that the local clock signal has a falling edge at the edge of the second reference clock signal corresponding to the rollover target code.

2. The clock generator of claim 1, wherein a frequency of the first reference clock signal is lower than a frequency of the local clock signal.

3. The clock generator of claim 1, further comprising a pulse generator configured to generate an injection signal corresponding to the edge of the second reference clock signal during each period of the second reference clock signal,
wherein the oscillator is configured such that a phase of the local clock signal is synchronized with the injection signal in response to the injection signal.

4. The clock generator of claim 1, wherein the DTC control circuit comprises:
an accumulator configured to output a phase code that is generated by accumulating values represented by the phase information;
a multiplexer configured to select the phase code or an estimation code and output the selected code as the DTC code; and
a rollover logic circuit configured to control the multiplexer to select the estimation code and generate the estimation code based on the phase error value.

5. The clock generator of claim 4, wherein the phase information corresponds to any one of a first phase value, which indicates that the phase of the local clock signal is advanced, or a second phase value, which indicates that the phase of the local clock signal is delayed.

6. The clock generator of claim 4, wherein, in response to the DTC code matching the bound reference code, the rollover logic circuit is configured to provide a rollover code corresponding to the estimation code to the accumulator,
the accumulator is configured to output the rollover target code by accumulating the rollover code to the phase code, and
the multiplexer is configured to output the rollover target code as the DTC code.

7. A clock generator comprising:
a Digital-to-Time Converter (DTC) configured to receive a first reference clock signal from outside the clock generator, and output a second reference clock signal by adjusting, a phase of the first reference clock signal received from outside the clock generator, based on a DTC code;
a pulse generator configured to generate an injection signal corresponding to an edge of the second reference clock signal during each period of the second reference clock signal;
an oscillator configured to generate a local clock signal with a phase synchronized with the injection signal, in response to the injection signal;
a phase detector configured to generate a phase error value based on a phase difference between the local clock signal and the second reference clock signal;
a rollover logic circuit configured to output an estimation code based on the phase error value;
an accumulator configured to output a phase code based on a value obtained by accumulating values represented by phase information received from outside the clock generator;
a multiplexer configured to output, as the DTC code, the phase code or the estimation code; and
the rollover logic circuit being further configured to provide the estimation code to the accumulator as a rollover code in response to the DTC code matching a bound reference code.

8. The clock generator of claim 7, wherein the rollover logic circuit is configured to:
in response to the DTC code being greater than a first estimation reference code, generate a clock gating signal in a first period; and
provide the clock gating signal to the pulse generator and control the pulse generator not to generate the injection signal during one period of the second reference clock signal, wherein the first estimation reference code is less than the bound reference code.

9. The clock generator of claim 8, wherein the first period is greater than a period of the first reference clock signal.

10. The clock generator of claim 8, wherein, in response to the DTC code being greater than the second estimation reference code, the rollover logic circuit is configured to generate the clock gating signal in a second period,
wherein the second period is less than the first period and greater than the period of the first reference clock signal, and
the second estimation reference code is greater than the first estimation reference code and less than the bound reference code.

11. The clock generator of claim 7, wherein, in response to the DTC code being greater than a first estimation reference code,
the rollover logic circuit is configured to control the multiplexer to output the estimation code as the DTC code,
the DTC is configured to adjust the phase of the second reference clock signal based on the estimation code received as the DTC code,
the phase detector is configured to output the phase error value based on a phase difference between the phase of the local clock signal and the phase of the second reference clock signal, which is adjusted based on the estimation code, and
the rollover logic circuit is further configured to correct the estimation code based on the phase error value.

12. The clock generator of claim 9, wherein the phase detector is configured to:
in response to the phase of the second reference clock signal, which is adjusted based on the estimation code, being delayed compared to the phase of the local clock signal, output a phase error value with a first error value; and
in response to the phase of the second reference clock signal, which is adjusted based on the estimation code, being advanced compared to the phase of the local clock signal, output a phase error value with a second error value.

13. The clock generator of claim 11, wherein the rollover logic circuit is configured to:
in response to the phase error value being a first error value, increase a rollover code corresponding to the estimation code by a first value; and
in response to the phase error value being a second error value, decrease the rollover code by the first value.

14. The clock generator of claim 13, wherein, in response to the DTC code being greater than the second estimation reference code, the rollover logic circuit is configured to:
in response to the phase error value being the first error value, increase the rollover code by a second value; and
in response to the phase error value being the second error value, decrease the rollover code by the second value, wherein the first value is greater than the second value.

15. The clock generator of claim 7, wherein the rollover logic circuit is configured to, in response to the DTC code being less than a first estimation reference code, generate a clock gating signal in a first period and provide the generated clock gating signal to the pulse generator to control the pulse generator not to generate the injection signal during one period of the second reference clock signal, wherein the first estimation reference code is greater than the bound reference code.

16. A device comprising:
a Phase Locked Loop (PLL) configured to generate a first reference clock signal;
a clock generator configured to generate a local clock signal based on the first reference clock signal; and
a Clock and Data Recovery (CDR) circuit configured to output phase information of the local clock signal based on the local clock signal and data received from outside the CDR,
wherein the clock generator comprises
a Digital-to-Time Converter (DTC) configured to output a second reference clock signal by adjusting, based on DTC code, a phase of the first reference clock signal;
an oscillator configured to generate a local clock signal synchronized to have a rising edge at an edge of the second reference clock signal,
a phase detector configured to generate a phase error value based on a phase difference between the local clock signal and the second reference clock signal; and
a DTC control circuit configured to output the DTC code based on the phase error value and the phase information,
wherein, in response to the DTC code matching a bound reference code, the DTC control circuit is further configured to update the DTC code to a rollover target code, and
the oscillator is further configured to adjust a phase of the second reference clock signal such that the local clock signal has a falling edge at the edge of the second reference clock signal corresponding to the rollover target code.

17. The device of claim 16, wherein a frequency of the first reference clock signal is lower than a frequency of the local clock signal.

18. The device of claim 16, further comprising a pulse generator configured to generate an injection signal corresponding to the second reference clock signal during each period of the second reference clock signal,
wherein the oscillator is configured such that a phase of the local clock signal is synchronized with the injection signal in response to the injection signal.

19. The device of claim 16, wherein the DTC control circuit comprises:
an accumulator configured to output a phase code that is generated by accumulating values represented by the phase information;
a multiplexer configured to select the phase code or an estimation code based on a selection signal and output the selected code as the DTC code; and
a rollover logic circuit configured to generate the selection signal for allowing the multiplexer to select the estimation code and generate the estimation code based on the phase error value.

20. The device of claim 19, wherein, in response to the DTC code matches the bound reference code, the rollover logic circuit is configured to provide a rollover code corresponding to the estimation code to the accumulator,
the accumulator is further configured to output the rollover target code by accumulating the rollover code to the phase code, and
the multiplexer is further configured to output the rollover target code as the DTC code.
